(19) United States
(12) Patent Application Publication
(10) Pub. No.: US 2004/0012936 A1
(43) Pub. Date: Jan. 22, 2004

(54) Device and method for enclosure of electronic printed circuit board based products

(76) Inventor: Pascal A. Gravelin, San Francisco, CA (US)

Correspondence Address: Ali Kamarei, INHOUSE IP Counsel, 280 Colorado Avenue, Palo Alto, CA, 94301, US

(21) Appl. No.: 10/198,012

(22) Filed: Jul. 18, 2002

(51) Int. Cl. H05K 3/28

(52) U.S. Cl. 361/771; 361/757; 29/841; 174/258

(57) ABSTRACT

The invention provides a device and method for enclosure of electronic circuits. An encapsulated electronic circuit device has a circuit board further comprising, electronic conductive paths, at least one electronic component, and an energy source, and an enclosure encapsulating the circuit board, substantially covering the front and back-side of the circuit board. The enclosure is composed of a polyurethane material. The circuit device preferably has a design imprinted on the front of the circuit board. The printing process is optionally a silk screening method.

### FIELD

The present invention relates generally to the packaging of electronic products. More specifically, this invention relates to packaging of dispensable electronic printed circuit board based products having an aesthetic design imprinted on the circuit board, using a low cost, variable and flexible design enclosure method.

### BACKGROUND

A traditional way to package an electronic product is to build an injection molded plastic casing to house the electronic product and its components. This means that tools or “tooling” need to be made to create the desired shape and form to be molded for the injection molded plastic housing. This also entails designing the housing to accommodate the electronic product and its components. Tooling is generally very expensive by nature (tens of thousand of dollars) and requires that production of the enclosure be made in large quantities (tens of thousand of pieces) or that the tools be used very often still with sizable number of pieces being made each time. This helps in redeeming the cost of the tools and produces cost-effective parts. However, for manufacture of small quantities of electronic product and components, this method of manufacture is too expensive and requires a large amount of up front money. If there is a need or desire to change the plastic molded enclosure's shape, new tooling has to be manufactured and additional expenses in tooling be repeated.

In addition to the enclosure, there is often a need for a complete front of the product graphic design or simply the print of a logo. This is traditionally done by silk printing directly onto the enclosure or by creating labels or stickers that are then placed onto the casing. Labels or stickers are not an adequate solution because there is a need to make many cut outs to clear electronic components such as LED's or switches when placing them directly onto a printed circuit board. This means that tools or tooling need to be made to create the desired number and sizes cut outs to clear the necessary components that are on the printed circuit board. These tools or tooling are generally very expensive by nature (tens of thousand of dollars) and require that production of the label or sticker be made in large quantities (tens of thousand of pieces) or that the tools be used very often still with sizable number of pieces being made each time. The method for silk screening directly onto the enclosure also suffers from the same disadvantages as production of the plastic injection molded enclosure itself.

Therefore, there is a need to make any shape and form printed circuit boards that would incorporate a graphic design and that would have a protective casing enclosure without the incurring cost of expensive and non flexible tools associated with techniques such as injection molding.

Furthermore, there is a need for an alternative packaging and enclosure that is best used on products that do not normally get repaired or are otherwise dispensable. This includes remote control devices, pagers, new type of vehicle LED's back lights, front panel for machines to replace what is know as overlays type of finish, and identification badges.

Additionally, there is a need for a low cost, lightweight, very thin electronic product that is by nature highly customizable and that incorporates a graphic design, as an alternative to the current injection molding techniques and placement of design labels and stickers upon electronic products.

A further need is to enclose electronic products using a method that is highly customizable in cost efficient. Another need is for an electronic hardware (printed circuit board) that can take any shape and form, incorporate a graphic design and be enclosed in an easy to make and apply protective enclosure.

### SUMMARY

The below described invention provides a device and method for enclosure of printed electronic circuit boards. An encapsulated electronic circuit device has a circuit board further comprising, electronic conductive paths, at least one electronic component, and an energy source, and an enclosure encapsulating the circuit board, substantially covering the front and back side of the circuit board. The enclosure is composed of a polyurethane material. The polyurethane material is cured upon the circuit board device, preferably using an ultra violet light (UV or UV light). The circuit device preferably has a design imprinted on the front of the printed electronic circuit. The printing process is optionally a silk screening method.

The method of manufacture of an encapsulated electronic circuit board comprises of first applying a graphic design to at least one side of a circuit board, second soldering electronic components upon the electronic circuit board, and third applying a polyurethane material onto one side of the circuit board so that the polyurethane material substantially covers at least one side of the electronic circuit board. The polyurethane material is optionally applied to both sides of the electronic circuit board, where it substantially covers both sides of the electronic circuit board including the electronic components that have been assembled upon the circuit board.

An advantage of the present invention is that it provides for the ability to make any shape and form printed circuit boards that would incorporate a graphic design and that would have a protective casing enclosure without the incurring cost of expensive and non flexible tools associated with techniques such as injection molding.

Another advantage of the present invention is that it provides for an alternative packaging and enclosure that is best used on products that do not normally get repaired or are otherwise dispensable. This includes remote control devices, pagers, new type of vehicle LED's back lights, front panel for machines to replace what is know as overlays type of finish, and identification badges.

Yet another advantage of the invention is that it provides a low cost, lightweight, very thin electronic product that is by nature highly customizable and that incorporates a graphic design, as an alternative to the current injection molding techniques and placement of design labels and stickers upon electronic products.

Another advantage of the present invention is that it encloses electronic products using a method that is highly customizable in cost efficient. A final advantage is that the present invention provides for an electronic device that can take any shape and form, incorporate a graphic design and be enclosed in an easy to make and apply protective enclosure.

### BRIEF DESCRIPTION OF DRAWINGS

FIGS. 1A through 1G show a cross section of the over all structure of a first embodiment of the invention showing the relation between the electronic components and enclosure housing.

FIGS. 2A and B through 5A and 5B show the method of manufacture of the electronic circuit board encapsulated by the enclosure.

### DETAILED DESCRIPTION

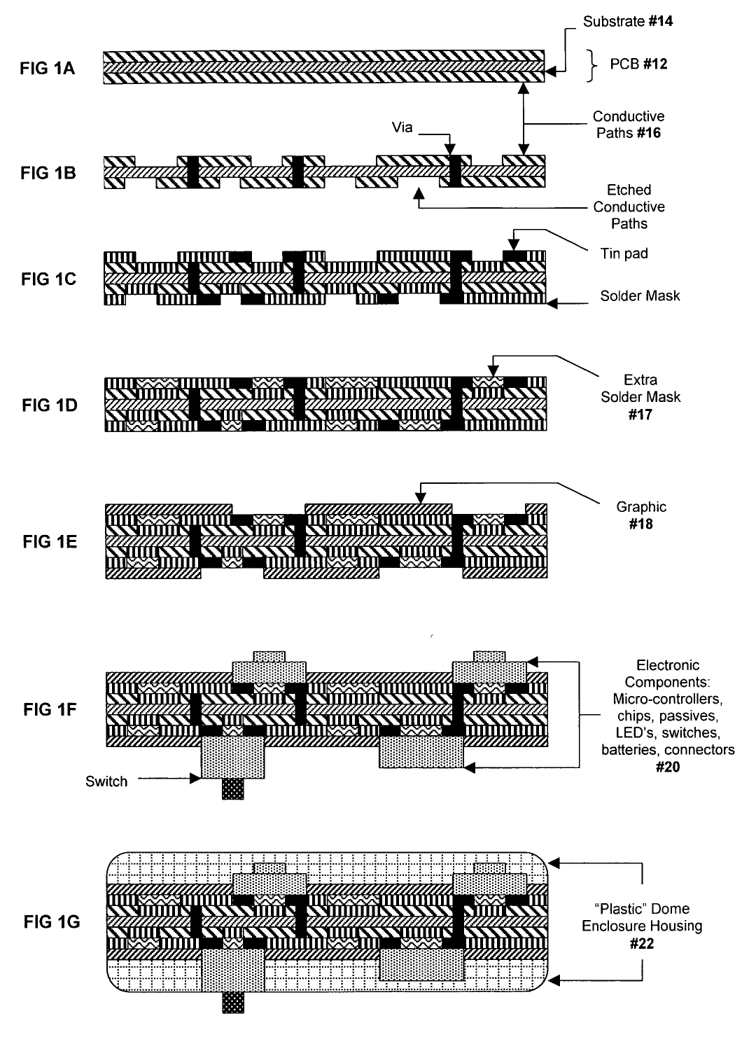

This invention provides a device and method for enclosure of electronic printed circuit board based products. Referring to FIGS. 1A through 1G, a printed circuit board 12 is formed of a substrate 14 having conductive paths 16 thereon. The printed circuit board can be made of any substrate with any type of conductive path layers and of any thickness. There is no restriction as to the nature or material of the circuit board. All types of printed circuit boards of any thickness may be optionally used.

Initially, substrate material has one side thereof coated with a conductive material. It is understood that both sides of the substrate material are optionally coated by the conductive material. This is known as two-layer printed circuit board. Additional layers can be inserted in between, in other words, the printed circuit board may optionally have more than two conductive layers. This is known as multi-layer printed circuit board. This is usually due to the creation of complex circuitry in need of conductive paths.

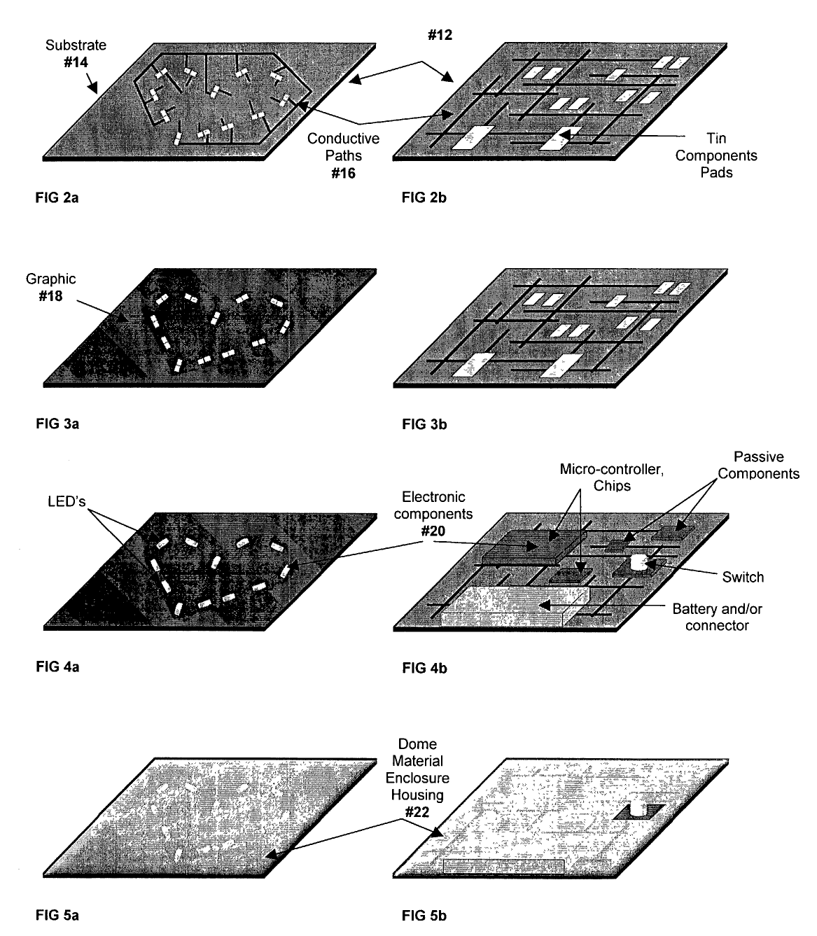

As is well known in making circuit boards, the conductive material is covered with a photo-resistant material and the desired circuit pattern is then exposed onto the photo-resistant covered conductive material in standard manner for the production of printed circuit boards. The conductive material is then etched away in standard fashion to leave only the desired conductive paths circuit or traces as shown in FIG. 1B and FIG. 1 and FIG. 2. This process usually leaves a printed circuit board with the conductive paths raised a bit from the substrate, leaving gaps between the conductive paths that were not etched away. This is a standard printed circuit board manufacturing process and does not form part of the invention. Further, any known type of printed circuit board manufacturing process could be used to form the basic circuit board of FIG. 1A.

Printed circuit boards are traditionally completely covered with a thin finishing layer of what is known as solder mask. The pads that are there to receive the electronic components are tinned plated. Depositing solder mask over the circuit board is to cover the conductive paths and to protect them from corrosion when expose to the ambient air. The present invention optionally has an additional step that is not traditionally performed. An extra layer of solder-mask 17 is applied to the one or both sides of the finished printed circuit board as shown in FIG. 1D. This extra layer or layers of solder mask are intended to fill the gaps between conductive paths so as to leave the printed circuit board substantially flat to the touch. As shown in FIG. 1C, which is a standard finished circuit board, a small difference in height between the conductive paths with solder mask and the etched conductive paths with solder mask can be noticed. By adding extra solder mask layer or layers 17 as shown in FIG. 1D the final result is a substantially smooth surface across the circuit board.

FIG. 1E and FIG. 3 show a graphic that can be applied using different techniques right onto the circuit board. The previous step helps with the printing. It is easier now to use techniques such as silk screening or pad printing to place a graphic onto the circuit board now that the surface is flat and smooth.

FIG. 1F, FIG. 5 and FIG. 6 show electronic components assembled and soldered onto the printed circuit board with graphic applied onto. Electronic components include but are not limited to a power source such as a battery, LEDs or other light emitting source, diodes, micro-controller chips, passives, switches, and connectors. In the present invention, if any graphics is to be applied to the printed circuit board, the graphics is applied before the electronic components 20 are assembled onto the electronic circuit board. The graphics printed onto the circuit board may serve to enhance the aesthetic look of the printed circuit board, preferably in conjunction with any LEDs mounted onto the circuit board. Additionally, the graphics printed onto the circuit board may have a functional purpose, indicating to the user of the electronic product to operate an electronic component, such as a switch. Finally, a sufficient amount of polyurethane material is poured and UV cured (hardened) onto the circuit board as shown in FIG. 1G and FIG. 7 and FIG. 8 of the manufacturing steps drawing to form an enclosure for the electronic circuit board and its components. Preferably, once cured, the polyurethane enclosure has a minimum thickness of approximately 1.5 millimeters. More preferably, once cured, the polyurethane enclosure has a thickness between 1.5 millimeters and 7 millimeters. Most preferably once cured, the polyurethane enclosure has a thickness between 1.5 millimeters and 3 millimeters. In another embodiment, a sufficient amount of polyurethane material is applied to both sides of the electronic circuit board to form an enclosure that substantially covers both sides of the electronic circuit board. This step forms a complete cover over the final assembly. The dome material is optionally clear when using LED's. This will assure the visibility of the light emitted by the LED. By covering both sides of the printed circuit board with a covering polyurethane material, an enclosure casing is created for the product.

The following are some key properties of dome covering polyurethane material. The process of “dome coating” is based on surface tension of the printed circuit board.

The Weatherometer ratings for the polyurethane is equivalent to 8,000 hours exposure, and it is suitable for most indoor/outdoor electronic products. If required, an automotive grade polyurethane is used for prolonged outdoor use, or for exposure to direct sunlight.

The polyurethane preferably has the following physical properties.

Key Properties

Non Yellowing

Excellent UV Resistance

High Gloss

Water Clear

Will Not Blush

Mechanical Properties

| | |
|---|---|
| Tensile Strength | 800 psi |
| Elongation | 200% |
| Shore Hardness | 50 D |

Chemical Resistance

| | |
|---|---|
| Salt Spray | Good |
| Mild bases | Good |
| Mild Acids | Good |
| Alcohol Solvents | Good |
| Aliphatic Hydrocarbon Solvents | Good |

Weathering Properties

1500 hours under QUV

2900 KJ/m² under Xenon Arc Weatherometer

113,000 Langleys on outdoor Florida Weathering (5 degrees from horizontal facing South)

From the aforementioned description, it is appreciated how the objectives and features of the above-described invention are met. First the present invention provides for the ability to make any shape and form printed circuit boards that would incorporate a graphic design and that would have a protective casing enclosure without the incurring cost of expensive and non flexible tools associated with techniques such as injection molding.

Second the present invention is that it provides for an alternative packaging and enclosure that is best used on products that do not normally get repaired or are otherwise dispensable. This includes remote control devices, pagers, new type of vehicle LED's back lights, front panel for machines to replace what is know as overlays type of finish, and identification badges.

Third, the present invention provides a low cost, lightweight, very thin electronic product that is by nature highly customizable and that incorporates a graphic design, as an alternative to the current injection molding techniques and placement of design labels and stickers upon electronic products.

Fourth, the present invention encloses electronic products using a method that is highly customizable in cost efficient.

Fifth, the present invention provides for an electronic device that can take any shape and form, incorporate a graphic design and be enclosed in an easy to make and apply protective enclosure.

This invention has been described with respect to a particular device and method of manufacture of an electronic circuit board having a protective covering of polyurethane material. The electronic circuit board optionally has a design imprinted upon it prior to the assembly of electronic components. However, it is appreciated that various modifications of the apparatus and method are possible without departing from the invention, which is defined by the claims set forth below.

1. An encapsulated electronic circuit device having:
a. a circuit board further comprising,
i. electronic conductive paths, at least one electronic component, and an energy source,
b. an enclosure encapsulating the circuit board, substantially covering the front and back side of the circuit board,
i. wherein the enclosure is of a polyurethane material.

2. The device of claim 1 wherein polyurethane material is cured upon the circuit device.

3. The device of claim 1 wherein the polyurethane enclosure has a minimum thickness of 1.5 millimeters.

4. The device of claim 1 wherein the polyurethane enclosure has a thickness between 1.5 millimeters and 7 millimeters.

5. The device of claim 1 wherein the polyurethane enclosure has a thickness between 1.5 millimeters and 3 millimeters.

6. The circuit device of claim 1 having a design imprinted on the front of the circuit board.

7. The circuit device of claim 3 wherein the design is silk screened upon the circuit board.

8. A method of manufacture of an encapsulated electronic circuit board, said method comprising the steps of:
a. first applying a graphic design to at least one side of a circuit board,
b. second soldering electronic components upon the electronic circuit board, and
c. third, applying a polyurethane material onto one side of the circuit board so that the polyurethane material substantially covers at least one side of the electronic circuit board.

9. The method of claim 8, wherein the polyurethane material is hardened upon the electronic circuit board by applying an ultra violet light to the polyurethane material.

10. The method of claim 8, wherein the graphic design is applied to the circuit board using a silk screening method.

11. The method of claim 8, wherein the polyurethane material is applied to both sides of the electronic circuit board.

12. The method of claim 11, wherein the polyurethane material substantially covers both sides of the electronic circuit board.
